(19) United States
(12) Patent Application Publication
(10) Pub. No.: US 2021/0210664 A1
(43) Pub. Date: Jul. 8, 2021

(54) LED CHIP AND METHOD FOR MANUFACTURING THE SAME

(71) Applicant: CHONGQING KONKA PHOTOELECTRIC TECHNOLOGY RESEARCH INSTITUTE CO., LTD., Chongqing (CN)

(72) Inventors: Chia-hung HUANG, Chongqing (CN); Shun-kuei YANG, Chongqing (CN); Ya-wen LIN, Chongqing (CN); Kuo-tung HUANG, Chongqing (CN)

(21) Appl. No.: 17/209,745

(22) Filed: Mar. 23, 2021

Related U.S. Application Data
(63) Continuation of application No. PCT/CN2019/125486, filed on Dec. 16, 2019.

(51) Int. Cl. H01L 33/60; H01L 33/06; H01L 33/00

(52) U.S. Cl. CPC H01L 33/60; H01L 2933/0058; H01L 33/007; H01L 33/06

(57) ABSTRACT

A light emitting diode (LED) chip and a method for manufacturing an LED chip are provided. The LED chip includes a sapphire layer, an N-type semiconductor layer, a light emitting layer, a P-type semiconductor layer, a P electrode, and an N electrode. The N-type semiconductor layer, the light emitting layer, the P-type semiconductor layer, the P electrode are sequentially disposed on a surface of the sapphire layer. The sapphire layer defines multiple preset patterns which extend through the sapphire layer, and the multiple preset patterns are used for reflecting a light of a preset wavelength through a channel defined by the sapphire layer.

### CROSS-REFERENCE TO RELATED APPLICATIONS

This application is a continuation of International Application No. PCT/CN2019/125486, filed on Dec. 16, 2019, the entire disclosure of which is incorporated herein by reference.

### TECHNICAL FIELD This disclosure relates to the technical field of semiconductors, and more particularly to a light emitting diode (LED) chip and a method for manufacturing an LED chip.

### BACKGROUND

An LED is a semiconductor electronic component that can convert electricity into light. For an existing white LED, “blue light+YAG phosphor” is usually adopted, in which phosphors for the wavelength range of blue light are used (the wavelength range is divided in units of 2.5 nm (nanometer)). YAG is the abbreviation of yttrium aluminum garnet, of which the chemical formula is Y₃Al₅O₁₂. YAG is a composite oxide obtained by a reaction between Y₂O₃ and Al₂O₃. YAG belongs to a cubic crystal system and has a garnet structure. For example, a white light can be controlled to be at the color coordinate position of X=0.33 and Y=0.33 according to commission internationale de l'eclairage (CIE) only when ratios of a phosphor in a mixed white light of 455 nm and a phosphor in a mixed white light of 450 nm are different, and in this way, the white light emitted can have a relatively narrow full width at half maximum (FWHM).

u-LED is a white light excited by the three primary colors (RGB), which is different from a white light excited by a “blue light+YAG phosphor” mode. If an existing LED chip is adopted, heat dissipation of the LED chip will be affected because of a high coverage rate of a sapphire layer. In addition, an FWHM of the emitted blue light will be wide, and on the other hand, lack of a red light source of the “blue light+YAG phosphor” mode will lead to a low color rendering and a low color temperature.

Therefore, the related art is in a need of improvement and development.

### SUMMARY

Considering disadvantages of the related art described above, implementations provide a light emitting diode (LED) chip and a method for manufacturing an LED chip.

Technical solutions of implementations are as follows.

In a first aspect, an LED chip is provided. The LED chip includes a sapphire layer, an N-type semiconductor layer, a light emitting layer, a P-type semiconductor layer, and an electrode. The N-type semiconductor layer, the light emitting layer, the P-type semiconductor layer, and the electrode are sequentially disposed on a surface of the sapphire layer. The sapphire layer defines multiple preset patterns which extend through the sapphire layer, and the multiple preset patterns are used for reflecting a light of a preset wavelength through a channel defined by the sapphire layer.

In some implementations, an inner surface of each of the multiple preset patterns is provided with a reflective layer.

In some implementations, the reflective layer is made of a metal, where the metal is any one of aluminum, copper, and gold.

In some implementations, the multiple preset patterns each have a width which is an integer multiple of a wavelength of a light emitted by the light emitting layer and smaller than a diameter of the LED chip.

In some implementations, the multiple preset patterns each are in a circular shape and/or a polygonal shape.

In some implementations, a distance between any two adjacent preset patterns is smaller than the diameter of the LED chip.

In some implementations, the electrode includes a P electrode and an N electrode, where the P electrode is disposed on a surface of the P-type semiconductor layer, and the N electrode is disposed on a surface of the N-type semiconductor layer away from the sapphire layer.

In some implementations, the light emitting layer is a multi-quantum well (MQW) active layer.

In a second aspect, a method for manufacturing an LED chip described in the first aspect is provided. The method includes the following. An N-type semiconductor layer, a light emitting layer, and a P-type semiconductor layer are disposed sequentially on a surface of a sapphire layer, a P electrode is disposed on the N-type semiconductor layer, and an N electrode is disposed on the N-type semiconductor layer. A preset pattern which extends through the sapphire layer is defined on the sapphire layer, where the preset pattern is used for reflecting a light of a preset wavelength through a channel defined by the sapphire layer.

In some implementations, the method includes the following. A metal reflective layer is coated on an inner surface of the preset pattern.

In a third aspect, a terminal device is provided. The display device includes the LED chip described in the first aspect.

### BRIEF DESCRIPTION OF THE DRAWINGS

FIG. 1 is a cross-sectional view of an LED chip according to implementations.

FIG. 2 is a diagram illustrating principles of an optical waveguide.

FIG. 3 is a cross-sectional view of a LED chip according to other implementations, in which a preset pattern is provided with a reflective layer.

FIG. 4 is a front view of a LED subjected to etching according to implementations.

### DETAILED DESCRIPTION

Implementations provide an LED chip and a method for manufacturing an LED chip. In order to make objectives, technical solutions, and effects of implementations clearer, implementations will be described in detail below with reference to the accompanying drawings and specific examples. It should be understood that, implementations described herein are merely intended for explaining, rather than limiting, the disclosure.

The sequence number of each component provided herein, such as “first”, “second”, and the like, is only used for distinguishing described objects without any indication of order or technical meaning. Terms “coupling”, “connection”, and the like, unless otherwise specified, include a direct coupling and an indirect coupling. It should be understood that directional relationship or positional relationship indicated by terms such as “on”, “under”, “front”, “back”, “left”, “right”, “vertical”, “horizontal”, “top”, “bottom”, “in”, “out”, “clockwise”, “anticlockwise”, “axial”, “radial”, “circumferential”, and the like is directional relationship or positional relationship based on accompanying drawings and is only for the convenience of description and simplicity, rather than explicitly or implicitly indicate that apparatuses or components referred to herein must have a certain direction or be configured or operated in a certain direction and therefore cannot be understood as limitation on the disclosure.

Unless stated otherwise, according to implementations, a first feature being “on” or “under” a second feature can refer to a direct contact between the first feature and the second feature or an indirect contact between the first feature and the second feature via a medium. In addition, the first feature being “above”, “over”, and “on” the second feature can be the first feature being right above or obliquely above the second feature or only refers to the first feature being at a higher horizontal level than the second feature. The first feature being “below”, “underneath”, and “under” the second feature can be the first feature being right below or obliquely below the second feature or only refers to the first feature being at a lower horizontal level than the second feature.

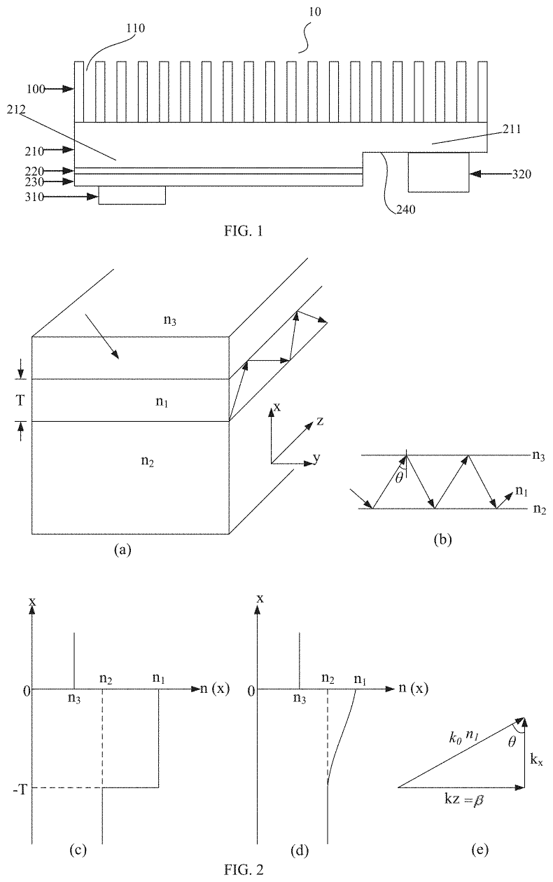

As illustrated in FIG. 1, an LED chip 10 includes a sapphire layer 100, an N-type semiconductor layer 210, a light emitting layer 220, a P-type semiconductor layer 230, a P electrode 310, and an N electrode 320. The N-type semiconductor layer 210, the light emitting layer 220, the P-type semiconductor layer 230, and the P electrode 310 are sequentially disposed on a surface of the sapphire layer 100. The N electrode 320 disposed on the N-type semiconductor layer 210. The sapphire layer 100 defines multiple preset patterns 110 which extend through the sapphire layer 100. The multiple preset patterns are used for reflecting a light of a preset wavelength through a channel defined by the sapphire layer.

In the LED chip provided herein, the multiple preset patterns are defined on the sapphire layer. Since the multiple preset patterns extend through the sapphire layer, a coverage rate of the sapphire layer can be reduced, which improves heat-dissipation efficiency of the LED chip. On the other hand, based on principles of an optical waveguide, light of a required wavelength can be extracted, to concentrate light of the required wavelength and block light of unnecessary wavelengths, which can improve color rendering on a display. As such, for light which can be perceived by human eyes, color shift will not be easy to perceive.

The N-type semiconductor layer 210 may be disposed on the surface of the sapphire layer 100. The N-type semiconductor layer 210 has a first portion 211 and a second portion 212. A mesa 240 is formed on the first portion 211. The mesa 240 has a depth which is smaller than the thickness of the N-type semiconductor layer 210.

The N electrode 320 is disposed on the mesa 240.

The light emitting layer 220 is disposed on the second portion 212 of the N-type semiconductor layer 210.

The P-type semiconductor layer 230 is disposed on a surface of the light emitting layer 220. The P electrode 310 is disposed on a surface of the P-type semiconductor layer 230.

The multiple preset patterns 110 extend through the sapphire layer 100 and reflect light emitted by the light emitting layer 220 through the channel defined by the sapphire layer 100.

The manner of forming each of these layers and the etching technology each belong to a common technology of the field, which will not be elaborated herein.

In some implementations, the multiple preset patterns 110 each have a width which is an integer multiple of a wavelength of the light emitted by the light emitting layer 220, and a channel of the preset pattern 110 defined by the sapphire layer 100 has a width which is smaller than a diameter of the LED chip.

According to implementations, the light emitted by the light emitting layer 220 is a white light excited by the three primary colors (RGB). The width of the preset pattern 110 is set to be an integer multiple of the wavelength of the light emitted by the light emitting layer 220, to ensure that light will be totally reflected a channel of the preset pattern 110 defined by the sapphire layer 100. Since the width of the preset pattern 110 can be accurately set according to actual needs, required light can be reflected according to the width of the preset pattern 110.

In addition, the multiple preset patterns 110 that extend through the sapphire layer is defined on the sapphire layer 100, such that the light emitted by the light emitting layer 220 of the LED chip 10 is a white light of which the wavelength is related to the size of the preset pattern 110 (that is, the width of the preset pattern is an integer multiple of the wavelength of the light emitted by the light emitting layer). By defining the multiple preset patterns 110 that extend through the sapphire layer 100, a coverage rate of the sapphire layer 100 can be reduced, which is possible to reduce heating of the LED chip 10. On the other hand, since the wavelength of a light reflected via the preset pattern 110 is a required wavelength, color rendering can be improved.

Principles of an optical waveguide of implementations are as follows.

Suppose that a guided wave light is a coherent monochromatic light, and that the optical waveguide is composed of a lossless, isotropic, and non-magnetic passive medium. Light is a kind of electromagnetic wave. Light of a specific wavelength will be confined in a specified space to achieve total reflection. As illustrated in (a)-(e) in FIG. 2, propagation of light in a slab waveguide can be regarded as total reflection of light at an interface between a substrate layer and a cover layer, and light is propagated along a zigzag path in a film layer. Light is propagated along a zigzag path in a Z direction of the waveguide, which is constrained in an x direction but not constrained in a y direction.

In a slab waveguide, refractive index n1>n2 and n1>n3, when incident angle θ₁ of an incident light is greater than threshold angle θ₀,

$$sin {θ}_{0} = \frac{{n}_{2}}{{n}_{1}}$$

The incident light is totally reflected. At this time, a phase jump occurs at a reflection point. According to Fresnel reflection formula:

$${R}_{TE} = \frac{{n}_{1} cos {θ}_{1} - \sqrt{{n}_{2}^{2} - {n}_{1}^{2} {sin}^{2} {θ}_{1}}}{{n}_{1} cos {θ}_{1} + \sqrt{{n}_{2}^{2} - {n}_{1}^{2} {sin}^{2} {θ}_{1}}}$$

$${R}_{TM} = \frac{{n}_{2}^{2} cos {θ}_{1} - {n}_{1} \sqrt{{n}_{2}^{2} - {n}_{1}^{2} {sin}^{2} {θ}_{1}}}{{n}_{2}^{2} cos {θ}_{1} + {n}_{1} \sqrt{{n}_{2}^{2} - {n}_{1}^{2} {sin}^{2} {θ}_{1}}}$$

phase jump φ_{TM} and φ_{TE} of the reflection point may be derived as follows:

$$tan {φ}_{TE} = \frac{\sqrt{{β}^{2} - {k}_{0}^{2} {n}_{2}^{2}}}{\sqrt{{k}_{0}^{2} {n}_{1}^{2} - {β}^{2}}}$$

$$tan {φ}_{TM} = \frac{{n}_{1}^{2} \sqrt{{β}^{2} - {k}_{0}^{2} {n}_{2}^{2}}}{{n}_{2}^{2} \sqrt{{k}_{0}^{2} {n}_{1}^{2} - {β}^{2}}}$$

β=k₀n₁ sin θ₁, where β is the propagation constant of light. k₀=2π/λ, where k₀ is the wave number of light in vacuum, and λ is the wavelength of light.

In order to ensure stable propagation of light in the waveguide, β is required to be as follows:

2kT−2ø₁₂−ø₁₃=2mπ, where m=0, 1, 2, 3, and so on.

k=k₀n₁ cos θ. ø₁₂ and ø₁₃ are phase differences of total reflection. T is the thickness of a waveguide. m is a mode number, which is a positive integer starting from zero. Therefore, only light of which the incident angle meets the above formula can be stably propagated in the optical waveguide, and the above formula is called a dispersion equation of slab waveguide.

Based on the above principles of an optical waveguide, according to implementations herein, the light emitted by the light emitting layer 220 enters, through the N-type semiconductor layer 210, a channel defined by the multiple preset patterns 110 in the sapphire layer 100. The preset pattern 110 may correspond to the slab waveguide. The width of the preset pattern 110 corresponds to the thickness (T) of a waveguide. The light emitted by the light emitting layer 220 is propagated along a zigzag path in the channel In this scenario, n₂=n₃, where n₂ is the refractive index of the sapphire layer 100. n₁ is the refractive index of the air. According to formula 2kT−2ø₁₂−ø₁₃=2mπ (m=0, 1, 2, 3, and so on), where k=k₀n₁ cos θ and k₀=2π/λ,

$$T = \frac{2 m π + 2 {∅}_{12} + {∅}_{13}}{4 {n}_{1} π cos θ} λ$$

can be derived, where m=0, 1, 2, 3, and so on, and ø₁₂ and ø₁₃ are phase differences of total reflection.

As an example, the multiple preset patterns 110 are defined on the sapphire layer 100 through exposure and development, where the preset pattern 110 includes, but is not limited to, a circular shape, a hexagonal shape, a square shape, an octagonal shape, and the like. The preset pattern 110 according to implementations is in a circular shape. All of the multiple preset patterns 110 may be in a circular shape or a polygonal shape, or the multiple preset patterns 110 may be a combination of a circular shape(s) and a polygonal shape(s). For example, the multiple preset patterns may be circular shapes and square shapes that are arranged and combined according to a predetermined rule, or may be square shapes and hexagonal shapes that are arranged and combined according to a predetermined rule.

After the circular shape is defined through exposure, a channel of the circular shape is defined through etching, where etching may be dry etching or wet etching. The channel of the circular shape obtained through etching has a diameter (that is, width) which is an integer multiple of the wavelength of light to-be-extracted, and the preset pattern 110 has a width which is smaller than the diameter of the LED chip 10. The channel of the circular shape has a depth which is equal to the thickness of the sapphire layer 100. A distance between two adjacent channels of the circular shape (e.g., a distance between two centers of a circle of two adjacent channels of the circular shape) may be M times the diameter of the channel of the circular shape, where M may be, for example, 1, 2, or the like, but a maximum distance between two adjacent channels is smaller than the diameter of the LED chip 10. FIG. 4 is a front view of the multiple preset patterns 110 in a circular shape defined on the sapphire layer 100.

The preset wavelength may be 455 nm˜465 nm, for example, 460 nm.

In practice, the preset wavelength may be determined according to the wavelength of the light emitted by the light emitting layer 220, and the disclosure is not limited in this regard.

As an example, if the wavelength of the light to-be-extracted is 400 nm, the diameter of the channel is 400 nm or N×400 nm, where N may be 1, 2, or the like, but a maximum diameter is smaller than the diameter of the LED chip. Similarly, if the wavelength of the light to-be-extracted is 550 nm, the diameter of the channel is 550 nm or N×550 nm, where N may be 1, 2, or the like, but a maximum diameter is smaller than the diameter of the LED chip 10. A standard thickness of the sapphire layer 100 is usually 600um, and accordingly the depth of the channel can be set to be 600 um. In other words, whatever the thickness of the sapphire layer 100 is, the sapphire layer 100 is required to be etched until the channel defined by the sapphire layer 100 extends to the N-type semiconductor layer 210.

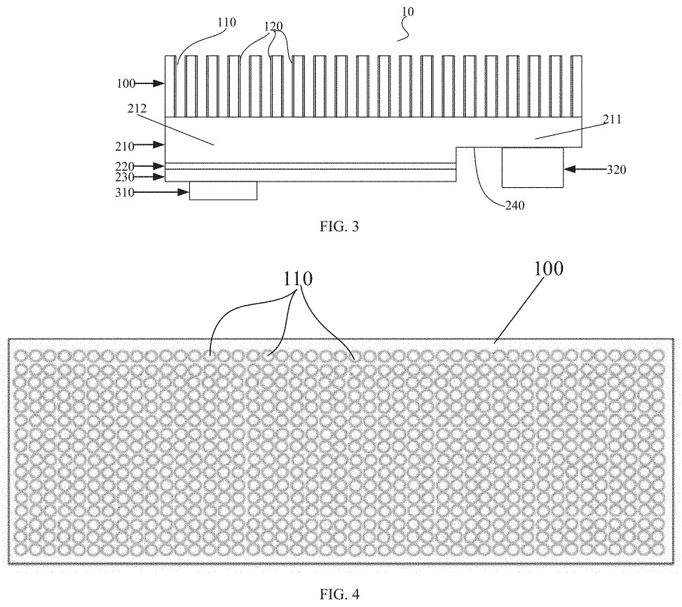

As illustrated in FIG. 3, in some implementations, an inner surface of the channel of the preset pattern 110 defined by the sapphire layer 100 is provided with a reflective layer 120 that is conducive to light reflection. For example, the inner surface of each of the multiple preset patterns can be plated with a layer of aluminum, copper, or gold to form the reflective layer 120. The thickness of the reflective layer 120 should satisfy the condition that the diameter of each of the channel of the preset pattern 110 provided with the reflective layer is an integer multiple of the wavelength of the light to-be-extracted and the multiple preset patterns each have a width which is smaller than the diameter of the LED chip.

In some implementations, the light emitting layer of the LED chip is a multi-quantum well (MQW) active layer. Light emitted by an MQW layer has a wavelength of 400 nm˜465 nm. If the MQW layer is used as the light emitting layer, light emitted by the MQW active layer is high in brightness. On the other hand, since the wavelength of light is restricted to 400 nm˜465 nm, the FWHM of light emitted by the LED chip can be controlled to be in a relatively narrow range.

Light emitted by the MQW layer reaches an external space from the MQW layer by passing sequentially through an N-GaN layer (that is, the N-type semiconductor layer) and the sapphire layer.

When the wavelength of the light emitted by the MQW layer is 400 nm˜465 nm, the wavelength of front light emitted by the LED chip provided herein will be limited to around 460 nm. It should be understood that, light can be totally reflected only in a specified space. If there is a need to extract light of a required wavelength, a channel for the wavelength of 455 nm or a channel for the wavelength of 465 nm fails to satisfy the condition of total reflection. Therefore, under a specific path, light will be emitted from other angles due to refraction, or be converted into heat without being emitted due to refraction (that is, loss), such that the wavelength of the front light emitted by the LED chip is limited to around 460 nm.

In addition, the LED chip provided herein can be combined with an LED chip with an existing “phosphor+package adhesive” structure, to achieve a similar technical effect.

Implementations further provide a method for manufacturing an LED chip. The method includes the following.

At block S100, an N-type semiconductor layer, a light emitting layer, and a P-type semiconductor layer are disposed sequentially on a surface of a sapphire layer, a P electrode is disposed on the P-type semiconductor layer, and an N electrode is disposed on the N-type semiconductor layer.

The process of manufacturing each layer and the material of each layer in operations at block S100 belong to the related art, which will not be elaborated herein.

At block S200, a preset pattern (or multiple preset patterns) which extends through the sapphire layer is defined on the sapphire layer, where the preset pattern is used for reflecting a light of a preset wavelength through a channel defined by the sapphire layer.

As an example, in operations at block S200, yellow light can be used along with a photomask to define the required preset pattern on the sapphire layer through exposure and development, and a channel of the preset pattern is obtained through etching. The diameter of the preset pattern and the distance between any two preset patterns can be set according to the wavelength of light to-be-extracted.

As an example, when the preset pattern obtained through etching is provided with a reflective layer, yellow light can used to form a metal layer on the preset pattern through vapor deposition or sputtering, which is conducive to reflection. The operations of using yellow light belong to the related art and will not be elaborated herein.

The LED chip provided herein may have a thickness of 5 μm (micrometer)˜10 μm, 10 μm˜50 μm, 50 μm˜100 μm, or 100 μm˜200 μm.

The LED chip provided herein may have a width of 2 μm˜5 μm, 5 μm˜10 μm, 10 μm˜20 μm, or 20 μm˜50 μm.

The LED chip provided herein may have a length of 2 μm˜5 μm, 5 μm˜10 μm, 10 μm˜20 μm˜, or 20 μm˜50 μm.

In the LED chip provided herein, multiple preset patterns are defined on the sapphire layer. Since the multiple preset patterns extend through the sapphire layer, a coverage rate of the sapphire layer can be reduced, which is beneficial to heat dissipation of the LED chip. On the other hand, based on principles of an optical waveguide, light of a required wavelength can be extracted from light emitted by the light emitting device, which can improve color rendering.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. A light emitting diode (LED) chip, comprising:
a sapphire layer;
an N-type semiconductor layer, a light emitting layer, a P-type semiconductor layer, and an electrode which are sequentially disposed on a surface of the sapphire layer; and
wherein the sapphire layer defines a plurality of preset patterns which extend through the sapphire layer, and the plurality of preset patterns are used for reflecting a light of a preset wavelength through a channel defined by the sapphire layer.

2. The LED chip of claim 1, wherein an inner surface of each of the plurality of preset patterns is provided with a reflective layer.

3. The LED chip of claim 2, wherein the reflective layer is made of a metal, wherein the metal is any one of aluminum, copper, and gold.

4. The LED chip of claim 1, wherein the plurality of preset patterns each have a width which is an integer multiple of a wavelength of a light emitted by the light emitting layer and smaller than a diameter of the LED chip.

5. The LED chip of claim 4, wherein the plurality of preset patterns each are in a circular shape and/or a polygonal shape.

6. The LED chip of claim 5, wherein a distance between any two adjacent preset patterns is smaller than the diameter of the LED chip.

7. The LED chip of claim 1, wherein the electrode comprises a P electrode and an N electrode, wherein the P electrode is disposed on a surface of the P-type semiconductor layer, and the N electrode is disposed on a surface of the N-type semiconductor layer away from the sapphire layer.

8. The LED chip of claim 1, wherein the light emitting layer is a multi-quantum well (MQW) active layer.

9. A method for manufacturing a light emitting diode (LED) chip, comprising:
disposing sequentially on a surface of a sapphire layer an N-type semiconductor layer, a light emitting layer, and a P-type semiconductor layer, disposing a P electrode on the P-type semiconductor layer, and disposing an N electrode on the N-type semiconductor layer; and
defining on the sapphire layer a plurality of preset patterns which extend through the sapphire layer, wherein the plurality of preset patterns are used for reflecting a light of a preset wavelength through a channel defined by the sapphire layer.

10. The method of claim 9, further comprising:
coating a metal reflective layer on an inner surface of the preset pattern.

11. The method of claim 10, wherein the reflective layer is made of a metal, wherein the metal is any one of aluminum, copper, and gold.

12. The method of claim 9, wherein the plurality of preset patterns each have a width which is an integer multiple of a wavelength of a light emitted by the light emitting layer and smaller than a diameter of the LED chip.

13. The method of claim 12, wherein the plurality of preset patterns each are in a circular shape and/or a polygonal shape.

14. The method of claim 13, wherein a distance between any two adjacent preset patterns is smaller than the diameter of the LED chip.

15. The method of claim 9, wherein the electrode comprises a P electrode and an N electrode, wherein the P electrode is disposed on a surface of the P-type semiconductor layer, and the N electrode is disposed on a surface of the N-type semiconductor layer away from the sapphire layer.

16. The LED chip of claim 9, wherein the light emitting layer is a multi-quantum well (MQW) active layer.

17. A terminal device, comprising a light emitting diode (LED) chip, wherein the light LED chip comprises:
a sapphire layer;
an N-type semiconductor layer, a light emitting layer, a P-type semiconductor layer, and an electrode which are sequentially disposed on a surface of the sapphire layer; and
wherein the sapphire layer defines a plurality of preset patterns which extend through the sapphire layer, and the plurality of preset patterns are used for reflecting a light of a preset wavelength through a channel defined by the sapphire layer.

18. The display device of claim 17, wherein an inner surface of each of the plurality of preset patterns is provided with a reflective layer.

19. The display device of claim 18, wherein the reflective layer is made of a metal, wherein the metal is any one of aluminum, copper, and gold.

20. The display device of claim 17, wherein the plurality of preset patterns each have a width which is an integer multiple of a wavelength of a light emitted by the light emitting layer and smaller than a diameter of the LED chip.
